(19) United States
(12) Patent Application Publication
(10) Pub. No.: US 2013/0199607 A1
(43) Pub. Date: Aug. 8, 2013

(54) HAIL RESISTANT PHOTOVOLTAIC MODULES

(71) Applicant: ANGELIQUE GENEVIEVE LUCIE GARREAU-ILES, Challonges (FR)

(72) Inventor: ANGELIQUE GENEVIEVE LUCIE GARREAU-ILES, Challonges (FR)

(73) Assignee: E I DU PONT DE NEMOURS AND COMPANY, Wilmington, DE (US)

(21) Appl. No.: 13/568,174

(22) Filed: Aug. 7, 2012

Related U.S. Application Data
(60) Provisional application No. 61/521,005, filed on Aug. 8, 2011.

(51) Int. Cl. H01L 31/048

(52) U.S. Cl. CPC H01L 31/048; H01L 31/0481
USPC 136/256; 438/64

(57) ABSTRACT

A photovoltaic module comprising a front sheet, a front encapsulant layer, at least one photoactive cell having a frontface and a backface, and a backing sheet, wherein the backface of the photoactive cell is in direct contact with the backing sheet.

### FIELD OF THE INVENTION

The present invention relates to hail resistant photovoltaic modules and methods for their manufacture.

### BACKGROUND OF THE INVENTION

Photovoltaic cells, sometimes called solar cells or photoactive cells, can convert light, such as sunlight, into electrical energy that can be used for multiple applications.

In practice, a plurality of photovoltaic cells are electrically connected together in series or in parallel to create an array of photovoltaic cells which can be inserted in a photovoltaic module.

In general, a module includes an array of photoactive cells that are connected in series by connecting the anode of one photovoltaic cell to the cathode of the next cell.

Photovoltaic cells, which can be very brittle and fragile, are most often protected from deterioration by being encapsulated in polymeric compositions.

For instance, in order to protect photovoltaic cells against ambient moisture or rain which could short-circuit the cell, an encapsulating composition is applied so as to insulate and waterproof the cell.

Furthermore, photovoltaic cells are encapsulated to be effectively protected against mechanical damages encountered during a lifetime of exposure to the elements, such as for example during hailstorms.

Hail can substantively damage a photovoltaic cell of a photovoltaic module. Upon impact of a hailstone onto the surface of a photovoltaic module, the kinetic energy of the hailstone is partially transferred to the impacted module, causing mechanical stress that eventually leads to the shattering of the photovoltaic cells.

A shattered photovoltaic cell or a cell having small cracks in it may partially or entirely cease to convert light energy to electrical energy, even though the photovoltaic module itself may not show exterior damage.

Depending on the severity of a hail storm, the hailstones can range, for example, from 1 centimeter in diameter falling at a rate of 9 meters per second (32.4 km/h), to 8 centimeters in diameter falling at a rate of 48 meters per second (172 km/h) and weighing, for example, 1 gram up to half a kilogram.

Because the photovoltaic modules are typically assembled by heat press lamination of the different layers, a damaged photovoltaic cell can not be replaced or repaired since the individual components are consolidated into one monolithic body, and consequently, the entire module has to be replaced at considerable economic cost.

In addition, the efficiency of photovoltaic modules often suffers from the degradation products of encapsulants used for the manufacture of the modules. These degradation products are formed by UV radiation or chemical degradation believed to be induced by peroxides, resulting in generation of for example acetic acid and/or chromophore formation, leading to a darkening of the encapsulant and/or to a corrosion of metal contacts.

Thus, there exists a long felt need to provide a photovoltaic module that is resistant against hail impact, and that can be manufactured at low cost, and that has a long service life, even when exposed to adverse environmental conditions.

### SUMMARY OF THE INVENTION

The present invention provides for a photovoltaic module comprising a front sheet, a front encapsulant layer, at least one photoactive cell having a frontface and a backface, and a backing sheet, wherein the backface of the photoactive cell is in direct contact with the backing sheet.

### DETAILED DESCRIPTION

For the purpose of the present disclosure, the term “backface” denotes the surface of a photovoltaic cell in a photovoltaic module which faces away from incident light, i.e. which faces the backing sheet.

For the purpose of the present disclosure, the term “frontface” denotes the surface of a photovoltaic cell in a photovoltaic module which faces towards incident light, i.e. which faces away from the backing sheet.

For the purpose of the present disclosure, the terms “direct contact” and “dry area” may be used interchangeably and denote a point or area of contact between two parts that is essentially void of any interjacent material.

For the purpose of the present disclosure, the term “light” means any type of electromagnetic radiation that can be converted into electric energy by a photovoltaic cell.

For the purpose of the present disclosure, the terms “photoactive” and “photovoltaic” may be used interchangeably and refer to the property of converting radiant energy (e.g., light) into electric energy.

For the purpose of the present disclosure, the terms “photovoltaic cell” or “photoactive cell” mean an electronic device that converts radiant energy (e.g., light) into an electrical signal. A photovoltaic cell includes a photoactive material layer that may be an organic or inorganic semiconductor material that is capable of absorbing radiant energy and converting it into electrical energy. The terms “photovoltaic cell” or “photoactive cell” are used herein to include solar cells with any types of photoactive layers including crystalline silicon, amorphous silicon, cadmium telluride, and copper indium gallium selenide (GIGS) photoactive layers.

For the purpose of the present disclosure, the term “photovoltaic module” (also “module” for short) means any electronic device having at least one photovoltaic cell.

For the purpose of the present disclosure, the term “encapsulant layer” refers to a layer of material that is designed to protect the photoactive cells from degradation caused by chemical and/or mechanical damage.

For the purpose of the present disclosure, the term “front encapsulant layer” refers to an encapsulant layer that is located between the frontface of a photoactive cell and the front sheet of the module. Typically, such front encapsulant layer also covers the edges of the photoactive cell.

For the purpose of the present disclosure, the term “back encapsulant layer” refers to an encapsulant layer that is located between the backface of a photoactive cell and the backing sheet of the module also known as the back-sheet.

The photovoltaic module according to the present invention comprises a front sheet, a front encapsulant layer, at least one photoactive cell having a frontface and a backface, and a backing sheet, wherein the backface of the photoactive cell is in direct contact with the backing sheet. In other words, the photovoltaic module of the present invention lacks any back encapsulant layer.

The front sheet of the photovoltaic module according to the present invention may be any front sheet as is conventional in the art of photovoltaic modules, i.e. the front sheet may be formed from any light transmitting material, which may be rigid or flexible and the thickness of the front sheet may be in the range of, for example, 50 to 4000 μm, as is conventional for front sheets of photovoltaic modules.

The function of the front sheet is to provide a transparent protective layer that will allow incident light (e.g., sunlight) to reach the frontface of the photovoltaic cell. The front sheet may be made of a rigid material, such as a glass, polycarbonate, acrylate polymer such as polymethylmethacrylate (PMMA) material, or a more flexible material, such as a fluoropolymer like for example polyvinyl fluoride (PVF), a polyvinylidene fluoride (PVDF), an ethylene tetrafluorethylene (ETFE) polymer, a perfluoroalkoxy vinyl polymer (PFA), an FEP copolymer of tetrafluoroethylene (TFE) and hexafluoropropylene (HFP), or a combination thereof. In general, the front sheet material may be any material that provides protection against the elements for the module while also providing transparency to the incident light. The front sheet may be a single layer of material, or may include more than one layer of material.

The front encapsulant layer of the photovoltaic module according to the present invention may be any front encapsulant layer as is conventional in the art of photovoltaic modules, i.e. the front encapsulant layer may be selected from various transparent polymeric materials and the thickness of the front encapsulant layer may be in the range of, for example, 100 to 1500 μm, as is conventional for front encapsulant layers of photovoltaic modules.

The front encapsulant layer of the photovoltaic module according to the present invention is located adjacent to and between the front sheet and the frontface of the at least one photoactive cell. The front encapsulant layer is designed to encapsulate and further protect the photoactive cells from environmental degradation and mechanical damage. The front encapsulant layer is transparent and allows the incident light to reach the photoactive cells.

The front encapsulant layer may be selected from various transparent polymeric materials, for example, one or more copolymers of ethylene with vinyl acetate (EVA), or any other unsaturated vinyl ester monomer, or in a further embodiment, the front encapsulant layer may comprise any ionomer. As used herein, the term “ionomer” means and denotes a thermoplastic resin containing both covalent and ionic bonds derived from ethylene copolymers. In some embodiments, monomers formed by partial neutralization of ethylene-methacrylic acid copolymers or ethylene-acrylic acid copolymers with inorganic bases having cations of elements from Groups I, II, or III of the Periodic table, notably, sodium, zinc, aluminum, lithium, magnesium, and barium may be used. The term ionomer and the resins identified thereby are well known in the art, as evidenced by Richard W. Rees, “Ionic Bonding In Thermoplastic Resins”, DuPont Innovation, 1971, 2(2), pp. 1-4, and Richard W. Rees, “Physical 30 Properties And Structural Features Of Surlyn Ionomer Resins”, Polyelectrolytes, 1976, C, 177-197.

Ionomers useful in the practice of the present invention may be copolymers obtained by the copolymerization of ethylene and an ethylenically unsaturated C3 to C8 carboxylic acid, such as for example methacrylic or acrylic acid.

The ethylene unsaturated acid copolymers may comprise from 8 wt % to 20 wt % of ethylenically unsaturated C3 to C8 carboxylic acid, based on the total weight of the copolymer.

Other suitable ionomers are further described in European patent EP1781735, which is herein incorporated by reference.

The front encapsulant layer can include more than one layer of encapsulant material, wherein each layer may include the same encapsulant material or an encapsulant material different from the other layer(s).

Other ethylene acid copolymers which can be used for the front encapsulant layer may be chosen from the group comprising ethylene/acrylic acid and ethylene/methacrylic acid copolymers; ethylene copolymers, ethylene/acid terpolymers, such as ethylene/vinyl acetate/acrylic acid polymers, ethylene/(meth)acrylic acid/alkyl(meth)acrylate polymers having C2 to C12 alkyl groups, like for example ethylene/acrylic acid/butyl acrylate polymers, polyurethanes and polyvinylbutyral polymers.

The front encapsulant layer may further comprise UV stabilization additives to prevent UV degradation of the encapsulant.

With regard to the at least one photoactive cell of the photovoltaic module of the present invention reference is made to the definition of the term “photoactive cell” given above.

It is currently widely believed within the technical field of photovoltaic modules that fully encapsulating the photovoltaic cells of a photovoltaic module is essential to achieve long service life.

In light of this prejudice, a separate back encapsulant layer is therefore believed to be a necessary part of a typical photovoltaic module.

Back encapsulant layers are designed to encapsulate and further protect the photoactive cells of a photovoltaic module, especially the surface of the photovoltaic cell facing away from incident light, called the backface.

The predominant opinion in the art of photovoltaic modules is that the back encapsulant layer protects the photoactive cell, and particularly its backface, against moisture and other elemental damage.

For example, the webpage “gosolar.eu” (http://www.gosolar.eu/de/photovoltaik/planung-aamp-technik/solarzellen-und-module/solarmodule.html) discloses a schematic drawing of a photovoltaic module where the photoactive cell (“kristalline Solarzelle”; English: “crystalline solar cell”) is protected on both sides with a polymeric or resinous encapsulant (“Einbettung in Kunststoff oder Giessharz”; English: “embedding in polymer or in casting resin”). In particular, the text of said webpage discloses that photovoltaic modules of the above structure are resistant to hail impacts of up to 2.5 cm in diameter (“die dementsprechend hergestellten Module sind gegen Hagelkörner von bis zu 2.5 cm geschützt”; English: “the so produced modules are protected against hailstones of up to 2.5 cm”).

Also, the webpage “Renewable Energy Concepts” (http://www.renewable-energy-concepts.com/german/sonnenenergie/solaranlage-solartechnik/solarmodule-aufbau.html) discloses a schematic drawing of a photovoltaic module where the photoactive cell is protected on both sides with a layer of EVA. The text of said webpage further describes the different layers of a photovoltaic module (“Die verschiedenen Schichten eines Photovoltaik Solarmoduls:”; English: “The different layers of a photovoltaic module:”), among which a front encapsulant film of EVA (“Obere Einbettfolie (EVA)”; English: “Upper embedding film (EVA)”) and a back encapsulant film of EVA (Untere Einbettfolie (EVA)”; English: “Lower embedding film (EVA)”) are laminated to both sides of the photovoltaic module under heat to form a watertight seal around the module.

Furthermore, the webpage “Energieroute.de”, (“http://www.energieroute.de/solar/solarmodule.php”) discloses a schematic drawing of a photovoltaic module where the photoactive cell is embedded in a transparent polymeric encapsulant (“Kunststoffeinbettung”; English: “polymer embedding”). The text of said webpage discloses that in the illustrated module, the photovoltaic cells are embedded in a polymeric encapsulant (“sind in . . . glasklarem Kunststoffmaterial eingebettet.”; English: “are embedded in crystal-clear polymer material”).

The above cited online references were found by querying the search engine “google.de” for the string “Solarmodule, Aufbau” (English: “solar modules, structure”) and selecting the topmost hits.

The 2^{nd} Edition of APPLIED PHOTOVOLTAICS, by S R Wenham/M A Green/M E Watt/R Corkish, ISBN 9781844074013, discloses on page 83 a schematic drawing of a typical laminated module structure (FIG. 5.17). The drawing depicts a typical encapsulation scheme, showing in this order, from top to bottom: a layer of glass, a layer of EVA, a layer of cells, a layer of EVA, and a layer of Tedlar® fluoropolymer film.

It is further the predominant opinion that the back encapsulant layer protects the photoactive cell, in particular its backface, against mechanical damage by cushioning the cell against mechanical blows from outside, such as hail impact, falling tree branches or unwary birds.

The photovoltaic module according to the present invention overcomes the aforementioned prejudice and it is characterized in that it lacks a back encapsulant layer, i.e. the contact area between the at least one photoactive cell and the backing sheet is a dry contact area.

Stated alternatively, the photovoltaic module according to the present invention is characterized in that the backface of the photovoltaic cell is in direct contact with the backing sheet of the module.

Therefore, the backface of the photovoltaic cell is not in contact with encapsulant material which could then adversely affect the efficiency of the cell by way of forming undesired degradation products.

In the photovoltaic module of the present invention, the at least one photoactive cell of the module is held in place by the front encapsulant layer covering the frontface of the at least one photoactive cell.

The photovoltaic module of the present invention comprises a backing sheet (also known as a back-sheet). The backing sheet of the photovoltaic module according to the present invention may be any backing sheet as is conventional in the art of photovoltaic modules, i.e. the backing sheet is formed from any rigid material, and the thickness of the backing sheet may be in the range of, for example, 500 μm to 2 cm, as is conventional for backing sheets of photovoltaic modules. The backing sheet has a Young's modulus of from 15 to 200 GPa, preferably of from 20 to 120 GPa, and more preferably of from 20 to 80 GPa when measured according to standard ISO 527 at a temperature of 23° C. at a relative humidity of 50%. It has been found that the use of a relatively stiff backing sheet, with a Young's modulus of from 15 to 200 GPa, in direct contact with the back side of the photovoltaic cell makes the photovoltaic cell more resistant to hail damage. The presence of a relatively stiff backing sheet directly against the solar cells without an intermediate encapsulant layer or other flexible layer provides direct support for the solar cells that make the solar cells resistant to hail damage.

The function of the backing sheet is to provide an electrically insulating layer that will reduce the risk of electrical shock in an operating photovoltaic module. The backing sheet is made of a rigid material, such as a glass, polyamide, polycarbonate, polyethylene terephthalate, fluoropolymer, epoxy resin, acrylate polymer such as polymethylmethacrylate (PMMA), glass fiber reinforced polymer, carbon fiber reinforced polymer, asbestos, and ceramic.

In general, the backing sheet material may be any material that provides electrical insulation and electrical shock protection.

The backing sheet may be a single layer of material, or may include more than one layer of material.

In the case where the backing sheet of the module includes more than one layer of material, it preferably includes a laminate consisting of one or more layers of polyethylene terephthalate sandwiched between polyvinyl fluoride (PVF) layers.

The present invention is further directed to a process for manufacturing the photovoltaic module of the present invention. In an embodiment, such process comprises the steps of
(a) assembling a stack by
   i. placing at least one photoactive cell on a backing sheet such that the at least one photoactive cell and the backing sheet are in direct contact to each other,
      ii. placing a sheet of front encapsulant on top of the at least one photoactive cell,
      iii. placing a front sheet on top of the front encapsulant sheet, and
   (b) consolidating the so assembled stack in a laminating device by
      i. heating the stack to a temperature of, for example, 100 to 180° C.,
      ii. subjecting the heated stack to a mechanical pressure in a direction perpendicular to the plane of the stack by decreasing the ambient pressure in the laminating device to, for example, 300 to 1200 mbar, and
      iii. cooling the stack to ambient temperature and releasing the mechanical pressure by reestablishing atmospheric pressure in the laminating device.

In the process for manufacturing the photovoltaic module, the step of assembling a stack by placing at least one photoactive cell on a backing sheet such that the at least one photoactive cell and the backing sheet are in direct contact to each other; placing a sheet of front encapsulant on top of the at least one photoactive cell; and placing a front sheet on top of the front encapsulant sheet may be carried out manually or automatically.

In the process for manufacturing the photovoltaic module, the step of assembling a stack may be carried out outside or inside a laminating device, and is preferably directly carried out inside a laminating device to reduce production cycle times.

A laminating device useful in the automatic process for manufacturing the photovoltaic module can be a heat press, for example.

In the process for manufacturing the photovoltaic module, the heating of the stack in the laminating device can be achieved by heating the top, lower, or both platen of the laminating device. The assembled stack is heated to a temperature of, for example, 100 to 180° C., in particular 120 to 170° C. and more particularly 130 to 150° C.

The heating of the stack allows the front encapsulant to soften, flow around and adhere to the photovoltaic cells, the front sheet and backing sheet. Thus, the front encapsulant serves as an adhesive that holds together the elements comprised in the photovoltaic module.

In the process for manufacturing the photovoltaic module, the mechanical pressure perpendicular to the plane of the heated stack may be exerted via the platen of the laminating device by decreasing the ambient pressure in the laminating device to, for example, 300 to 1200 mbar, in particular 500 to 1000 mbar and more particularly 600 to 900 mbar. The decrease of the ambient pressure in the laminating device facilitates the removal of air pockets trapped between the different layers of the stack.

The consolidation step of the process for manufacturing the photovoltaic module ends with the cooling of the stack to ambient temperature and the release of the mechanical pressure by reestablishing atmospheric pressure in the laminating device.

### EXAMPLES

The following Examples are intended to be illustrative of the present invention, and are not intended in any way to limit the scope of the present invention described in the claims.

### Testing of Resistance Against Damp Heat:

A photovoltaic Module 1 of 30×30 cm having a single crystalline silicon photovoltaic cell from Gintech was obtained by stacking a sheet of fluorinated ethylene polymer (FEP) of 125 um thickness, a sheet of ethylene vinyl acetate copolymer (EVA) of 450 um thickness, the photovoltaic cell, a sheet of float glass of 3 mm thickness and subsequently laminating the stack of layers together in a 3S laminator at a temperature of 140° C. for 19 minutes with a pressure of 900 mbar.

A photovoltaic Module 1c (comparative) of 30×30 cm having a single crystalline silicon photovoltaic cell from Gintech was obtained by stacking a sheet of fluorinated ethylene polymer (FEP) of 125 um thickness, a sheet of ethylene vinyl acetate copolymer (EVA) of 450 um thickness, the photovoltaic cell, a sheet of ethylene vinyl acetate copolymer (EVA) of 450 um thickness, a sheet of float glass of 3 mm thickness, and subsequently laminating the stack of layers together in a 3S laminator at a temperature of 140° C. for 19 minutes with a pressure of 900 mbar.

A photovoltaic Module 2 of 30×30 cm having a single crystalline silicon photovoltaic cell from Gintech was obtained by stacking a sheet of fluorinated ethylene polymer (FEP) of 125 um thickness, a sheet of ionomer (commercially obtainable under the designation “PV5300” from E. I. du Pont de Nemours and Company, of Delaware, USA) of 1.5 mm thickness, the photovoltaic cell, a sheet of float glass of 3 mm thickness and subsequently laminating the layers together in a 3S laminator at a temperature of 150° C. for 29 minutes with a pressure of 600 mbar.

A photovoltaic Module 2c (comparative) of 30×30 cm having a single crystalline silicon photovoltaic cell from Gintech was obtained by stacking a sheet of fluorinated ethylene polymer (FEP) of 125 um thickness, a sheet of a ionomer (commercially obtainable under the designation “PV5300” from E. I. du Pont de Nemours and Company, of Delaware, USA) of 1.5 mm thickness, the photovoltaic cell, a sheet of a ionomer (commercially obtainable under the designation “PV5300” from E. I. du Pont de Nemours and Company, of Delaware, USA) of 1.5 mm thickness, a sheet of float glass of 3 mm thickness and subsequently laminating the layers together in a 3S laminator at a temperature of 150° C. for 29 minutes with a pressure of 600 mbar.

A photovoltaic Module 3 of 30×30 cm having a single crystalline silicon photovoltaic cell from Gintech was obtained by stacking a sheet of fluorinated ethylene polymer (FEP) of 125 um thickness, a sheet of ionomer (commercially obtainable under the designation “PV5400” from E. I. du Pont de Nemours and Company, of Delaware, USA) of 0.5 mm thickness, the photovoltaic cell, a sheet of float glass of 3 mm thickness and subsequently laminating the layers together in a 3S laminator at a temperature of 150° C. for 29 minutes with a pressure of 600 mbar.

A photovoltaic Module 3c (comparative) of 30×30 cm having a single crystalline silicon photovoltaic cell from Gintech was obtained by stacking a sheet of fluorinated ethylene polymer (FEP) of 125 um thickness, a sheet of ionomer (commercially obtainable under the designation “PV5400” from E. I. du Pont de Nemours and Company, of Delaware, USA) of 0.5 mm thickness, the photovoltaic cell, a sheet of ionomer (commercially obtainable under the designation “PV5400” from E. I. du Pont de Nemours and Company, of Delaware, USA) of 0.5 mm thickness, a sheet of float glass of 3 mm thickness and subsequently laminating the layers together in a 3S laminator at a temperature of 150° C. for 29 minutes with a pressure of 600 mbar.

The thus obtained Modules 1, 1 c, 2, 2c, 3 and 3c were then placed in an aging chamber in damp heat at 85° C. at 85% relative humidity for 100, 500 and 1000 hours. At each aging stage, the power generated by the module was measured when the module was exposed to a radiation of 1000W per square meter, according to the IEC61215 standard. For each module, the change in power generation was then computed in percent when compared to virgin module (0 hours). Results are shown in Table 1.

TABLE 1

| | | | % change in |
|---|---|---|---|
| | % change in | % change in | power, 1000 |
| | power, 100 hours | power, 500 hours | hours |
| 1 | −3 | −29 | −28 |
| 1c | −6 | −34 | −38 |
| 2 | −1 | −1 | −9 |
| 2c | −1 | −3 | −7 |
| 3 | 0 | 1 | −2 |
| 3c | −2 | 0 | −2 |

Table 1 shows the percent change in power generation for Modules 1, 1c, 2, 2c, 3 and 3c when exposed to 85° C. at 85% relative humidity for 100, 500 and 1000 hours. The percent change is computed by comparison to a virgin module (0 hours). To measure power generation in the tested modules, the Modules where irradiated with 1000W per square meter, according to the IEC61215 standard.

As can be seen in Table 1, power generation for the photovoltaic module comprising ethylene vinyl acetate copolymer (EVA) as front encapsulant only (Module 1) decreases less than for the photovoltaic module with ethylene vinyl acetate copolymer (EVA) on both sides of the photovoltaic cell (Module 1c). In contrast, modules comprising ionomer encapsulants show less variation in time (Modules 2, 2c, 3, 3c).

### Testing of Resistance Against Hail Impact:

A photovoltaic Module 4 of 30 cm×30 cm having a single crystalline silicon photovoltaic cell from Sunpower was obtained by stacking a sheet of float glass of 3 mm thickness, the photovoltaic cell, a sheet of ethylene vinyl acetate copolymer (EVA) of 450 um thickness and an ethylene tetrafluoroethylene polymer (ETFE) front sheet of 50 um thickness, and subsequently laminating the layers together in a 3S laminator at 140° C. for 19 minutes at 900 mbar.

A photovoltaic Module 4c (comparative) of 30 cm×30 cm having a single crystalline silicon photovoltaic cell from Sunpower was obtained by stacking a sheet of float glass of 3 mm thickness, a sheet of ethylene vinyl acetate copolymer (EVA) of 450 um thickness, the photovoltaic cell, another sheet of ethylene vinyl acetate copolymer (EVA) of 450 um thickness and an ethylene tetrafluoroethylene polymer (ETFE) front sheet of 50 um thickness, and subsequently laminating the layers together in a 3S laminator at 140° C. for 19 minutes at 900 mbar.

A photovoltaic Module 5 of 30 cm×30 cm having a single crystalline silicon photovoltaic cell from Sunpower was obtained by stacking a sheet of float glass of 3mm thickness, the photovoltaic cell, two sheets of ethylene vinyl acetate copolymer (EVA) of 450 um thickness each and an ethylene tetrafluoroethylene polymer (ETFE) front sheet of 50 um thickness, and subsequently laminating the layers together in a 3S laminator at 140° C. for 19 minutes at 900 mbar.

A photovoltaic Module 5c (comparative) of 30 cm×30 cm having a single crystalline silicon photovoltaic cell from Sunpower was obtained by stacking a sheet of float glass of 3 mm thickness, a sheet of ethylene vinyl acetate copolymer (EVA) of 450 um thickness, the photovoltaic cell, another two sheets of ethylene vinyl acetate copolymer (EVA) of 450 um thickness each and an ethylene tetrafluoroethylene polymer (ETFE) front sheet of 50 um thickness, and subsequently laminating the layers together in a 3S laminator at 140° C. for 19 minutes at 900 mbar.

The thus obtained modules 4, 4c, 5 and 5c were then laid out flat, ETFE front sheet facing up, on a rigid support to be then tested for hail impact. A solid steel ball having a diameter of 23 mm and a weight of 63.6 g was dropped from a height of 80 cm onto the front face of the modules to simulate the kinetic energy of a hailstone having a diameter of 12.5 mm at its terminal velocity of 16 m/s.

The damage to the photovoltaic cells in the module was then assessed using the following electroluminescence technique.

By passing an electrical current through the cell of the module, light is emitted by the cell in the near infra-red wavelength. The ability of the cell to emit light under electrical current is proportional to its ability to convert light into current. Low efficiency areas, such as cracks, will therefore appear as darker areas in images of the cells.

During the hail impact tests, the impacting steel ball caused cracks to form in the photovoltaic cells of the Modules 4c and 5c comprising both a front encapsulant layer of EVA and a back encapsulant layer, with Module 5c showing fewer and smaller cracks because of the additional EVA layer on the frontside of the cell. In contrast, even fewer cracks than were formed in the photovoltaic cells of Modules 4c and 5c were formed in the photovoltaic cell of the Module 4 having only a front encapsulant layer and no back encapsulant layer at all. No cracks at all form in Module 5 which had twice the amount of front encapsulant when compared to Module 4. Thus, it can be seen that the modules according to the present invention have unexpectedly superior hail resistance when compared to conventional modules having encapsulants on both sides of the photovoltaic cell.

What is claimed is:

1. A photovoltaic module comprising a front sheet, a front encapsulant layer, at least one photoactive cell having a frontface and a backface, and a backing sheet, wherein the backface of the photoactive cell is in direct contact with the backing sheet and the backing sheet has a Young's modulus of from 15 to 200 GPa when measured according to standard ISO 527 at a temperature of 23° C. at a relative humidity of 50%.

2. The photovoltaic module of claim 1, wherein the backing sheet is made of glass, polyamide, polycarbonate, polyethylene terephthalate, fluoropolymer, epoxy resin, acrylate polymer, glass fiber reinforced polymer, carbon fiber reinforced polymer, asbestos, ceramic, or a combination thereof.

3. The photovoltaic module of claim 1, wherein the front encapsulant layer is made of an ethylene with vinyl acetate (EVA) or an ionomer.

4. The photovoltaic module of claim 2, wherein the front encapsulant layer is made of an ethylene with vinyl acetate (EVA) or an ionomer.

5. The photovoltaic module of claim 1, wherein the front sheet is made of a polyvinyl fluoride (PVF), a polyvinylidene fluoride (PVDF), an ethylene tetrafluorethylene (ETFE) polymer, a perfluoroalkoxy vinyl polymer (PFA) or an FEP copolymer of tetrafluoroethylene (TFE) and hexafluoropropylene (HFP)), or a combination thereof.

6. A process for the manufacture of a photovoltaic module comprising the steps of:
(a) assembling a stack by
i. placing at least one photoactive cell on a backing sheet having a Young's modulus of from 15 to 200 GPa when measured according to standard ISO 527 at a temperature of 23° C. at a relative humidity of 50%, such that the at least one photoactive cell and the backing sheet are in direct contact to each other,
ii. placing a sheet of front encapsulant on top of the at least one photoactive cell, and
iii. placing a front sheet on top of the front encapsulant sheet,
(b) consolidating the so assembled stack in a laminating device by
i. heating the stack to a temperature of 100 to 180° C.,
ii. subjecting the heated stack to a mechanical pressure in a direction perpendicular to the plane of the stack by decreasing the ambient pressure in the laminating device to 300 to 1200 mbar, and
iii. cooling the stack to ambient temperature and releasing the mechanical pressure by reestablishing atmospheric pressure in the laminating device.
